(19) United States
(12) Patent Application Publication
(10) Pub. No.: US 2015/0262681 A1
(43) Pub. Date: Sep. 17, 2015

(54) NON-VOLATILE SEMICONDUCTOR MEMORY DEVICE

(71) Applicant: KABUSHIKI KAISHA TOSHIBA, Tokyo (JP)

(72) Inventor: Koji HOSONO, Fujisawa Kanagawa (JP)

(21) Appl. No.: 14/469,508

(22) Filed: Aug. 26, 2014

(30) Foreign Application Priority Data
Mar. 17, 2014 (JP) 2014-052946

(51) Int. Cl. G11C 16/10; G11C 16/04

(52) U.S. Cl. CPC G11C 16/10; G11C 16/0483

(57) ABSTRACT

A non-volatile semiconductor memory device includes a memory cell array that includes a plurality of memory cells stacked on a semiconductor substrate, a voltage generating circuit that generates voltages for a memory cell selected for writing and for non-selected memory cells, and a control unit that controls the voltage generating circuit to supply the voltages to the memory cells. Normally, a write voltage is supplied to the selected memory cell, a first voltage lower than the write voltage to the memory cell adjacent to the selected memory cell, and a second voltage lower than the first voltage to the memory cell separated from the selected memory cell by one memory cell. However, if there are not enough memory cells between the selected memory cell and the semiconductor substrate, the second voltage is not supplied.

### CROSS-REFERENCE TO RELATED APPLICATION

This application is based upon and claims the benefit of priority from Japanese Patent Application No. 2014-052946, filed Mar. 17, 2014, the entire contents of which are incorporated herein by reference.

### FIELD

Embodiments described herein relate generally to a non-volatile semiconductor memory device.

### BACKGROUND

Recently, a stacked semiconductor memory (BiCS: Bit Cost Scalable Flash Memory) in which memory cells are stacked has been developed. With this BiCS, a high-capacity semiconductor memory may be achieved at a low cost.

### DESCRIPTION OF THE DRAWINGS

FIG. 1 is a diagram illustrating an overall configuration example of a non-volatile semiconductor device according to a first embodiment.

FIG. 2 is a cross-sectional view illustrating a memory cell array according to the first embodiment.

FIG. 3 is an equivalent circuit diagram illustrating the memory cell array according to the first embodiment.

FIG. 4A is a conceptual diagram illustrating a write operation of memory cells according to the first embodiment when a word line WL20 is selected.

FIG. 4B is a conceptual diagram illustrating a write operation of memory cells according to the first embodiment when a word line WL21 is selected.

FIG. 4C is a conceptual diagram illustrating a write operation of memory cells according to the first embodiment when a word line WL22 is selected.

FIG. 4D is a conceptual diagram illustrating a write operation of memory cells according to the first embodiment when a word line WL23 is selected.

FIG. 4E is a conceptual diagram illustrating a write operation of memory cells according to the first embodiment when a word line WL24 is selected.

FIG. 4F is a conceptual diagram illustrating a write operation of memory cells according to the first embodiment when a word line WL25 is selected.

FIG. 4G is a conceptual diagram illustrating a write operation of memory cells according to the first embodiment when a word line WL26 is selected.

FIG. 5A is a conceptual diagram illustrating a write operation of memory cells according to a second embodiment when a word line WL20 is selected.

FIG. 5B is a conceptual diagram illustrating a write operation of memory cells according to the second embodiment when a word line WL21 is selected.

FIG. 5C is a conceptual diagram illustrating a write operation of memory cells according to the second embodiment when a word line WL22 is selected.

FIG. 5D is a conceptual diagram illustrating a write operation of memory cells according to the second embodiment when a word line WL23 is selected.

FIG. 5E is a conceptual diagram illustrating a write operation of memory cells according to the second embodiment when a word line WL24 is selected.

FIG. 5F is a conceptual diagram illustrating a write operation of memory cells according to the second embodiment when a word line WL25 is selected.

FIG. 5G is a conceptual diagram illustrating a write operation of memory cells according to the second embodiment when a word line WL26 is selected.

FIG. 6A is a conceptual diagram illustrating a write operation of memory cells according to a third embodiment when a word line WL20 is selected.

FIG. 6B is a conceptual diagram illustrating a write operation of memory cells according to the third embodiment when a word line WL21 is selected.

FIG. 6C is a conceptual diagram illustrating a write operation of memory cells according to the third embodiment when a word line WL22 is selected.

FIG. 6D is a conceptual diagram illustrating a write operation of memory cells according to the third embodiment when a word line WL23 is selected.

FIG. 6E is a conceptual diagram illustrating a write operation of memory cells according to the third embodiment when a word line WL24 is selected.

FIG. 6F is a conceptual diagram illustrating a write operation of memory cells according to the third embodiment when a word line WL25 is selected.

FIG. 6G is a conceptual diagram illustrating a write operation of memory cells according to the third embodiment when a word line WL26 is selected.

### DETAILED DESCRIPTION

The present embodiment now will be described more fully hereinafter with reference to the accompanying drawings, in which various embodiments are shown. In the drawings, the thickness of layers and regions may be exaggerated for clarity. Like numbers refer to like elements throughout. As used herein the term “and/or” includes any and all combinations of one or more of the associated listed items and may be abbreviated as “/”.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element such as a layer or region is referred to as being “on” or extending “onto” another element (and/or variations thereof), it may be directly on or extend directly onto the other element or intervening elements may also be present. In contrast, when an element is referred to as being “directly on” or extending “directly onto” another element (and/or variations thereof), there are no intervening elements present. It will also be understood that when an element is referred to as being “connected” or “coupled” to another element (and/or variations thereof), it may be directly connected or coupled to the other element or intervening elements may be present. In contrast, when an element is referred to as being “directly connected” or “directly coupled” to another element (and/or variations thereof), there are no intervening elements present.

It will be understood that, although the terms first, second, etc. may be used herein to describe various elements, components, regions, layers and/or sections, these elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, if the structure in the Figure is turned over, elements described as being on the “backside” of substrate would then be oriented on “upper” surface of the substrate. The exemplary term “upper”, may therefore, encompass both an orientation of “lower” and “upper,” depending on the particular orientation of the figure. Similarly, if the structure in one of the figures is turned over, elements described as “below” or “beneath” other elements would then be oriented “above” the other elements. The exemplary terms “below” or “beneath” may, therefore, encompass both an orientation of above and below.

Embodiments are described herein with reference to cross sections and perspective illustrations that are schematic illustrations of embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

A non-volatile semiconductor memory device capable of improving operational capability is provided.

According to one embodiment, there is provided a non-volatile semiconductor memory device including a memory cell array that includes a plurality of memory cells stacked above a semiconductor substrate, a voltage generating circuit that generates voltages for a memory cell selected for writing and for non-selected memory cells, and a control unit that controls the voltage generating circuit to supply the voltages to the memory cells. If at least a first number of memory cells is between the selected memory cell and the semiconductor substrate, the control circuit applies a first rule, according to which the voltage generating circuit supplies a write voltage to the selected memory cell, a first voltage lower than the write voltage to non-selected memory cells adjacent to the selected memory cell, and a second voltage lower than the first voltage to non-selected memory cells separated from the selected memory cell by one non-selected memory cell. If less than a second number of memory cells is between the selected memory cell and the semiconductor substrate, the control circuit applies a second rule, according to which the voltage generating circuit supplies the write voltage to the selected memory cell and the first voltage to the non-selected memory cells adjacent to the selected memory cell, but does not supply the second voltage to the non-selected memory cells separated from the selected memory cell by one non-selected memory cell.

Hereinafter, a first embodiment will be described with reference to the accompanying drawings. In this description and the drawings, like components are represented by like reference numerals. However, the drawings are schematic, and it should be noted that a relationship between a thickness and a planar dimension, a ratio of the thickness of each layer, and the like may differ from the actual ones. Accordingly, a specific thickness or dimension should be determined based on the following description. Moreover, it should be understood that a dimensional relationship and a ratio of a portion may vary depending on the drawings.

In the first embodiment described below, when data is written, an appropriate voltage is applied to a gate included in a back gate element that joins adjacent memory cells having a stacked structure to each other.

### First Embodiment

### Overall Configuration Example

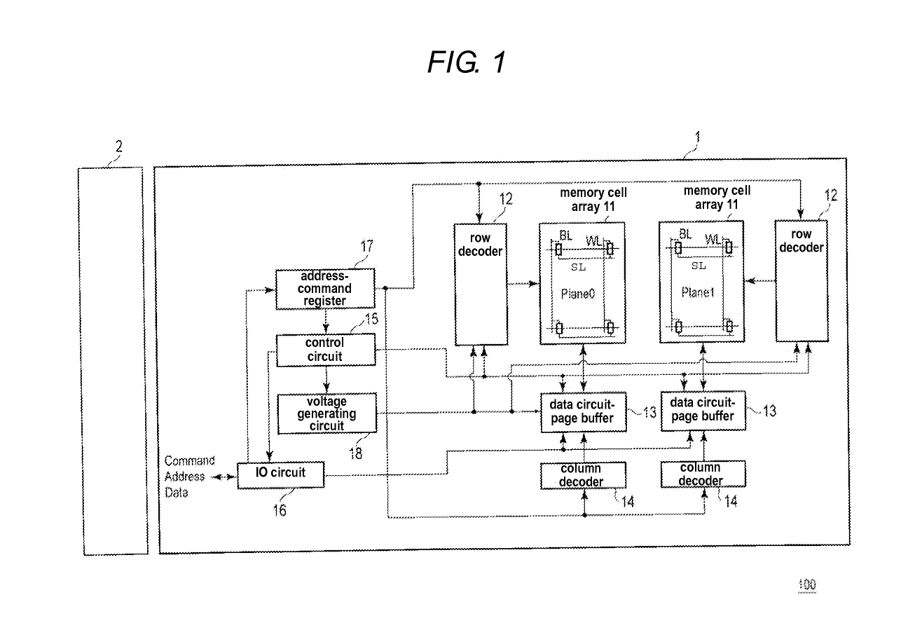

An overall configuration of a non-volatile semiconductor memory device according to the first embodiment will be described with reference to FIG. 1. FIG. 1 is a block diagram illustrating a memory system 100 including a memory device 1, which is the non-volatile semiconductor memory device according to the first embodiment, and an outside controller 2 electrically connected to the memory device 1 and configured to control the memory device 1.

As illustrated in FIG. 1, the non-volatile semiconductor memory device according to the first embodiment includes a memory cell array 11, a row decoder 12, a data circuit-page buffer 13, a column decoder 14, a control circuit 15, an input-output circuit 16, an address-command register 17, and an internal voltage generating circuit 18.

### 1. Memory Cell Array

As illustrated in FIG. 1, the memory cell array 11 includes, for example, a plane P0 and a plane P1 (in FIG. 1, indicated by Plane0 and Plane1). These planes P0 and P1 include plural memory strings MS. Bit lines BL, word lines WL, and source lines SL are electrically connected to these memory strings MS.

As will be described below, the memory string MS includes plural memory cells MC that are connected in series to each other, and the above-described word lines WL are connected to a control gate CG included in the memory cell MC.

Here, although the case where the non-volatile semiconductor memory device includes the planes P0 and P1 is described as an example, the number of planes P included in the non-volatile semiconductor memory device is not limited. When the planes P0 and P1 do not need to be distinguished from each other, these planes will be simply referred to as the planes P.

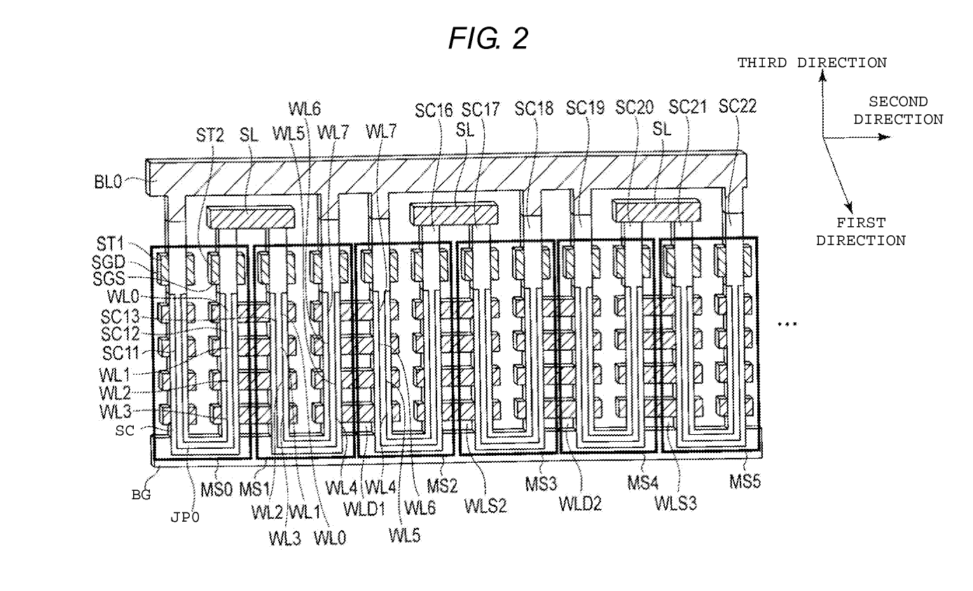

Hereinafter, the detailed configuration of the planes P will be described with reference to FIG. 2.

### 1.1 Cross-Sectional View of Sub-Block SB

Next, a conceptual diagram of a cross-sectional view of the memory cell array 11 will be described with reference to FIG. 2 focusing on a bit line BL0. As illustrated in FIG. 2, the bit line BL0 is provided with the plural memory strings MS, and a group of plural memory strings (for example, 12 strings) will be referred to as a sub-block SB.

Each sub-block SB is provided with one bit line BL.

A group of sub-blocks SB will be referred to as a block BLK. That is, an aggregate of the plural memory strings MS which are connected to the bit lines BL0 to BLn (n: natural number) not illustrated, respectively, is the block BLK.

The sub-block SB includes, for example, 12 memory strings MS, that is, memory strings MS0 to MS11. However, here, memory strings MS0 to MS5 are only illustrated in the drawing for convenience of description.

### 1.1.1 Regarding Memory Strings MS0 to MS5

As illustrated in FIG. 2, the memory strings MS0 to MS5 (thick line) are provided along a cross-sectional direction.

In each of the memory strings MS, columnar semiconductor layers SC11 and SC12 are formed on a semiconductor layer BG toward a third direction perpendicular to first and second directions. Hereinafter, when the semiconductor layers SC11 and SC12 do not need to be distinguished from each other, the semiconductor layers will be simply referred to as the semiconductor layers SC.

Next, the semiconductor layers SC adjacent to each other along the first direction are joined to each other through a joining portion JP provided inside the semiconductor layer BG. For example, the semiconductor layers SC11 and SC12 are joined to each other through a joining portion JP0 provided inside the semiconductor layer BG. With such a configuration, a U-shaped memory string MS0 is formed.

Since other pairs including a pair of semiconductor layers SC13 and SC14, . . . , and a pair of semiconductor layers SC21 and SC22 have the same configuration, the description thereof will be omitted.

In addition, plural polysilicon layers which are formed along the third direction are provided inside each of the memory strings MS. Some of the polysilicon layers function as the word lines WL, and the other polysilicon layers function as select signal lines SGS and SGD.

The select signal lines SGS and SGD are provided at positions between which the word lines WL are interposed. That is, as illustrated in FIG. 2, when the number of word lines WL is, for example, 4, word lines WL3, WL2, WL1, and WL0 and the select signal line SGS are stacked on the semiconductor layer BG in this order from below while insulating films are interposed between the respective layers. Likewise, word lines WL4, WL5, WL6, and WL7 and the select signal line SGD are stacked on the semiconductor layer BG in this order from below while insulating films are interposed between the respective layers.

Accordingly, a select transistor ST1, a memory cell MC7, a memory cell MC6, . . . , a memory cell MC1, a memory cell MC0, and a select transistor ST2 are provided using the semiconductor layers SC, the select signal lines SGS and SGD, and the word lines WL.

These select signal lines SGS and SGD function as the select signal lines SGS and SGD for controlling the selection and non-selection of the memory strings MS.

In FIG. 2, a case where the memory string MS0 includes the memory cells MC0 to MC7 is illustrated as an example, but the present disclosure is not limited thereto. In a write operation described below, it is assumed that the memory string MS includes 48 memory cells MC, that is, memory cells MC0 to MC47.

The configuration of the memory cell array 11 is disclosed in, for example, “Three-dimensional stacked non-volatile semiconductor memory”, U.S. patent application Ser. No. 12/407,403, filed on Mar. 19, 2009. In addition, the configuration of the memory cell array 11 is also disclosed in “Three dimensional stacked non-volatile semiconductor memory”, U.S. patent application Ser. No. 12/406,524, filed on Mar. 18, 2009, “Non-volatile semiconductor storage device and method of manufacturing the same”, U.S. patent application Ser. No. 12/679,991, filed on Mar. 25, 2010, and “Semiconductor memory and method for manufacturing the same”, U.S. patent application Ser. No. 12/532,030, filed on Mar. 23, 2009. The entire contents of these patent applications are incorporated in this disclosure by reference.

### 1.1.2 Regarding Bit Line BL and Source Line SL

Tips of semiconductor layers SC11 and SC14, semiconductor layers SC15 and SC18, and semiconductor layers SC19 and SC22 penetrate the select signal lines SGD, which are commonly connected through the bit line BL0, respectively.

In addition, tips of semiconductor layers SC12 and SC13, semiconductor layers SC16 and SC17, and a semiconductor layer SC20 and SC21 penetrate the select signal lines SGS, which are connected to source lines SL, respectively. That is, for example, the semiconductor layers SC11 and SC12 and the semiconductor layers SC13 and SC14 which are adjacent to each other are commonly connected through the source lines SL.

### 1.1.3 Regarding Bit Lines BL1 to BLm−1

In the above description, the bit line BL0 is focused, and bit lines BL1 to BLm−1 have the same configuration as that of the bit line BL0.

That is, semiconductor layers SC connected to the bit line BLi (i: natural number, 1≦i≦m−1) will be referred to as “semiconductor layers SCi1 to SC(i+10)”. In this case, the above-described select signal line SGS, the word lines WL0 to WL7, and the select signal line SGD penetrate the semiconductor layers SCi1 to SC(i+10) such that plural memory strings MS corresponding to the respective bit lines BLi are formed.

Regarding each memory string MS corresponding to the bit line BLi, the semiconductor layers SCi1 and SCi2 and the semiconductor layers SCi3 and SCi4 which are adjacent to each other are commonly connected through the source line SL.

Here, the case where each memory string MS includes the memory cells MC0 to MC7 and the select transistors ST1 and ST2 is described as an example, but the number of memory cells MC is not limited. That is, the number of memory cells MC may be 16 or 32. Hereinafter, as necessary, the number of memory cells MC will also be referred to as “s (s: natural number)”.

In this way, Plane0 is formed by arranging the memory cells MC, which electrically store data, in a three-dimensional matrix shape. That is, the memory cells MC are arranged in a matrix shape not only in a stacking direction but in a horizontal direction perpendicular to the stacking direction. The plural memory cells MC which are arranged in the stacking direction as above are connected in series, and the memory string MS is formed by the plural memory cells MC connected in series to each other.

In addition, dummy memory cells described below (hereinafter, referred to as “dummy memory cells MCDD, MCDS, MCDBD, and MCDBS”) are not illustrated in the drawings.

### 1.1.4 Circuit Diagram of Memory Cell Array 11

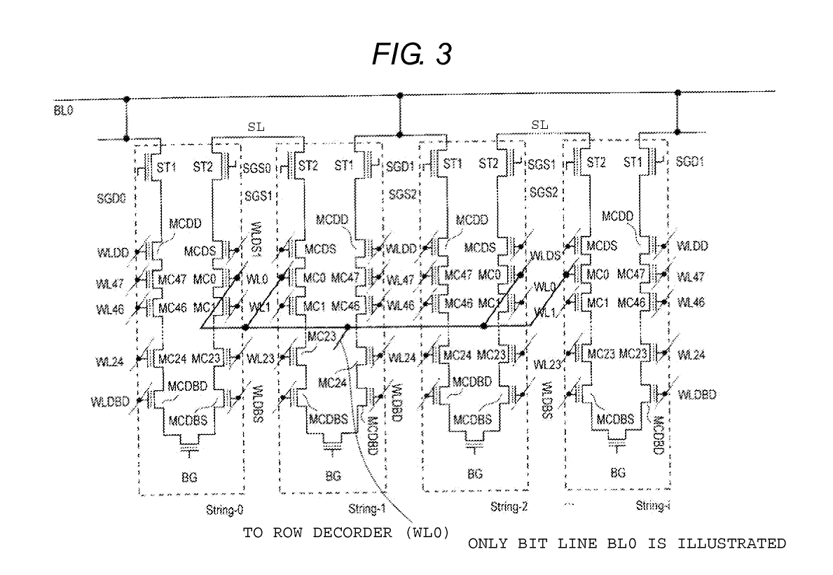

Next, an equivalent circuit of the above-described planes P will be described with reference to FIG. 3. Here, the bit line BL0 is focused, and since the respective configurations of the memory strings MS0 to MSi (in the drawings, MS0 to MSi; i: positive real number) are the same, the memory string MS0 will be described in the following description. In addition, it is assumed that the number of memory cells MC included in each memory string MS is 48 (s=48).

### Regarding Memory String MS0

As illustrated in FIG. 3, the memory string MS0 includes memory cells MC0 to MC47, a back gate transistor BG, dummy memory cells MCDD, MSDS, MCDBD, and MCDBS, and select transistors ST1 and ST2. Although the dummy memory cell MCDD includes two dummy memory cells MCDD0 and MCDD1, will be referred to as the dummy memory cell MCDD for convenience of description. The same shall be applied to the dummy memory cell MCDS.

As described above, control gates CG of the memory cells MC0 to MC47 are connected to the corresponding word lines WL, respectively. That is, 48 word lines WL are connected to the memory string MS0.

The memory cells MC0 to MC23 are connected in series between the select transistor ST2 and the dummy memory cell MCDS; and the dummy memory cell MCDBS and the back gate transistor BG.

A second end of a current path of the select transistor ST2 is connected to the source line SL, and a signal SGS_0 is supplied to a gate of the select transistor ST2. A first end of a current path of the memory cell MC23 is connected to a first end of a current path of the back gate transistor BG, and a signal BG is supplied to a gate BG of the back gate transistor BG.

Further, a signal line DS is connected to a gate of the dummy memory cell MCDS. In addition, a gate line DBS is connected to a gate of the dummy memory cell MCDBS.

In addition, the memory cells MC24 to MC47 are connected in series between the select transistor ST1 and the dummy memory cell MCDD; and the dummy memory cell MCDBD and the back gate transistor BG.

A first end of a current path of the select transistor ST1 is connected to the bit line BL, and a signal SGD_0 is supplied to a gate of the select transistor ST1. A first end of a current path of the memory cell MC24 is connected to a second end of the current path of the back gate transistor BG.

Further, a signal line DD is connected to a gate of the dummy memory cell MCDD. In addition, a signal line DBD is connected to a gate of the dummy memory cell MCDBD.

Next, the respective control gates CG of the memory cells MC0 to the memory cells MC47 which are provided inside the above-described memory strings MS0 to MSi are commonly connected. That is, for example, when the control gates CG of the memory cells MC0 provided inside the memory strings MS0 to MSi are noted, the control gates CG are commonly connected to the word line WL0.

The control gates CG of the memory cells MC1 to MC47 are commonly connected to the word lines WL1 to WL47, respectively.

All the memory cells MC0 which are provided inside the memory strings MS0 to MSi connected to other bit lines BL_1 to BL_m (not illustrated) are also commonly connected to the word line WL0.

In this way, the common connection ranges of the word lines WL are determined based on, for example, the specification of a non-volatile semiconductor memory device, the size and the interconnection of the memory cells MC, and the size of the transistors. For example, when it is assumed that the page length (page is the unit of data access) corresponding to a direction in which the bit lines BL are arranged is 8 KB, the length of the memory string MS is 16 memory cells connected in series to each other, the common range between the memory strings MS in a direction moving along the bit lines BL is 4 strings, and the data memory capacity of each memory cell MC is 2 bit/cell, the memory capacity in the memory string MS which is common to the word lines WL is 1 MB (=8 KB×16×4×2). Here, this range will be referred to as a block BLK.

Although this non-volatile semiconductor memory device performs a read operation and a write operation in units of the above-described page length, the non-volatile semiconductor memory device performs an erase operation in units of the above-described block BLK. The size of the above-described block BLK is merely an example and is not particularly limited.

### 1.2 Row Decoder 12

Referring to FIG. 1 again, the row decoder 12 (hereinafter, also referred to as “block decoder 12”) will be described. The row decoder 12 decodes a block address signal and the like input from the address-command register 17, and selects a desired word line WL according to the decoding result.

A voltage generated from the internal voltage generating circuit 18 is applied to the select word line WL.

### 1.3 Data Circuit-Page Buffer 13

The data circuit-page buffer 13 includes a sense amplifier SA and a data cache DC which are not illustrated. That is, using the sense amplifier SA and the data cache DC, the data circuit-page buffer 13 reads and writes data, transfers read data to an external device, and stores write data.

Here, the writing of data will be described in detail.

A non-volatile semiconductor memory device 1 receives not only a command and an address for loading data transferred from a memory controller 2 but data.

The data circuit-page buffer 13 receives this data through the input-output circuit 16, and stores the write data in the data cache DC.

Next, the sense amplifier SA performs a predetermined operation at a time corresponding to an instruction from the control circuit 15 and writes the data, which is stored in the data cache DC, in a select memory cell MC.

### 1.4 Column Decoder 14

The column decoder 14 decodes a column address signal input from the address-command register 17 and selects a column direction of the memory cell array 11.

### 1.5 Control Circuit 15

The control circuit 15 controls the overall operation of the non-volatile semiconductor memory device. That is, The control circuit 15 performs a write sequence of a write operation of data based on a control signal, a command, and an address supplied from the address-command register 17.

In order to perform this sequence, the control circuit 15 controls an operation of each circuit block included in the non-volatile semiconductor memory device 1.

For example, the control circuit 15 controls the internal voltage generating circuit 18 to generate predetermined voltages and controls predetermined times at which the predetermined voltages are output to the word lines WL and the bit lines BL through the row decoder 12 and the data circuit-page buffer 13.

In addition, the control circuit 15 stores a sequence program for outputting the predetermined voltages to the word lines WL, dummy word lines WLD, and signal lines BG during the write operation.

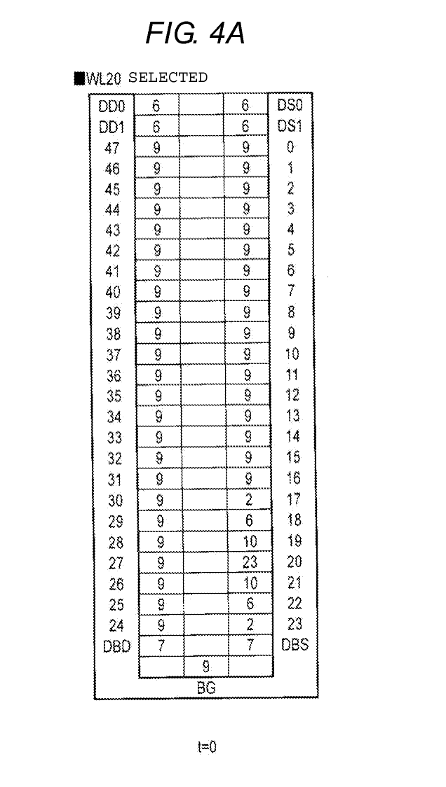

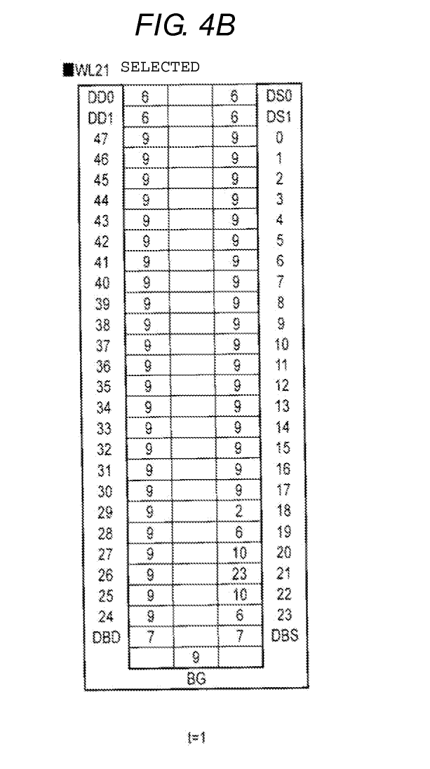

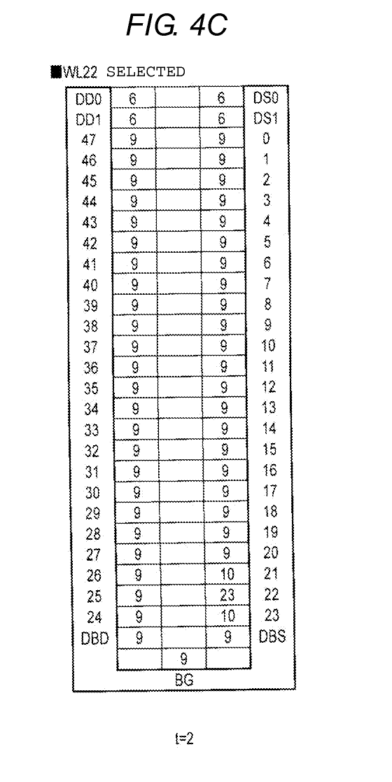

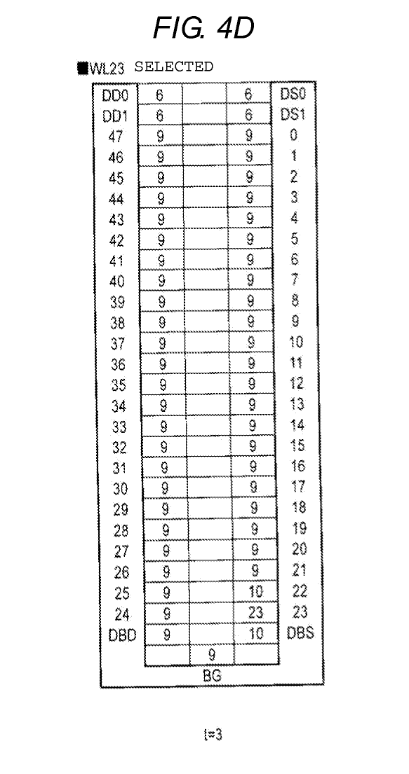

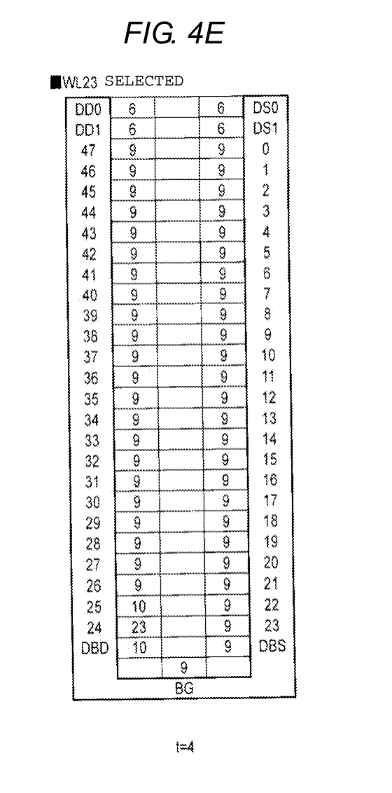

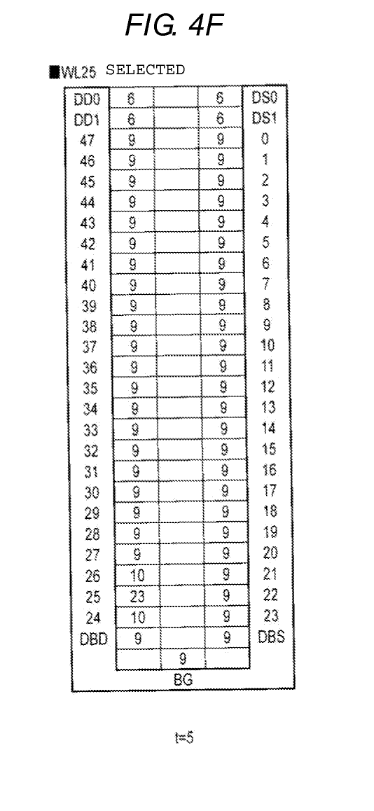

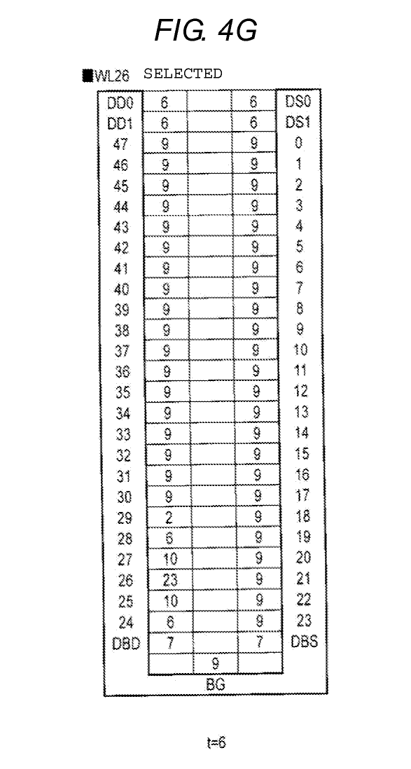

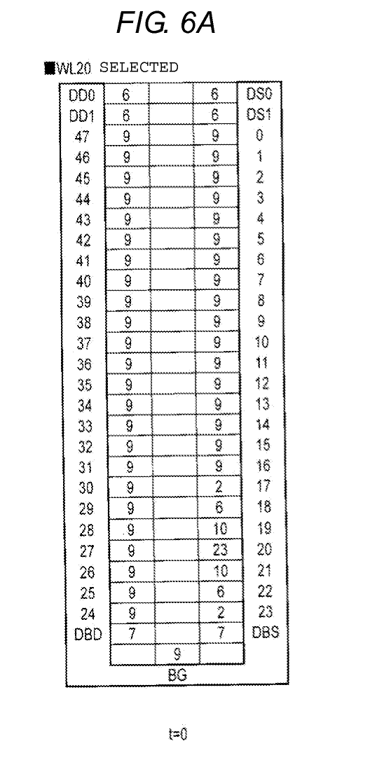

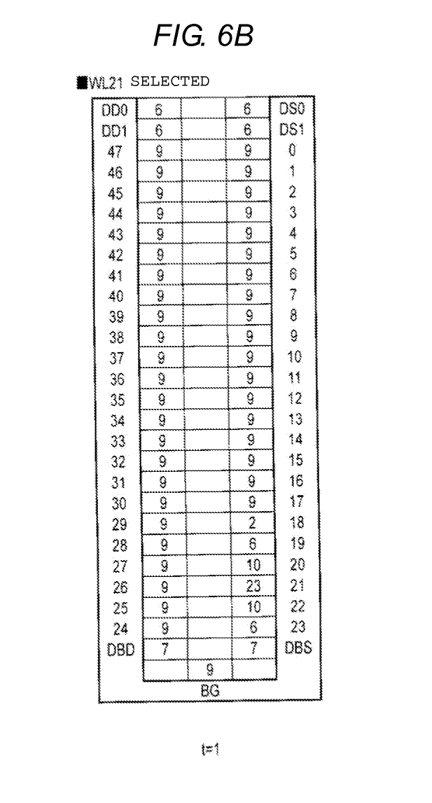

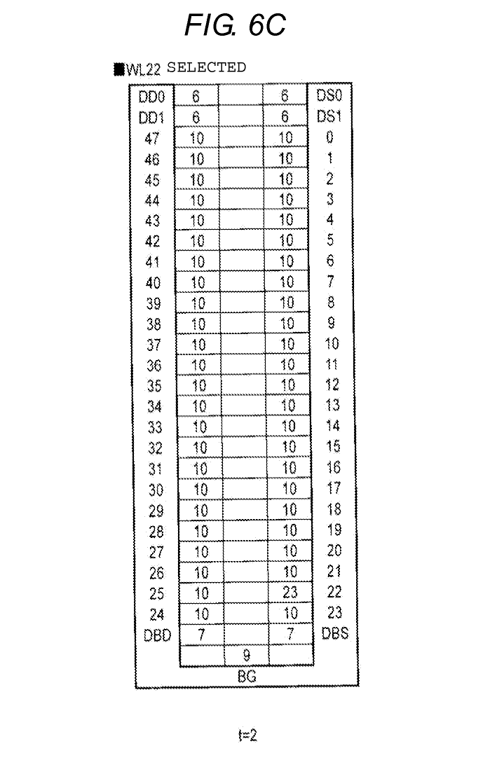

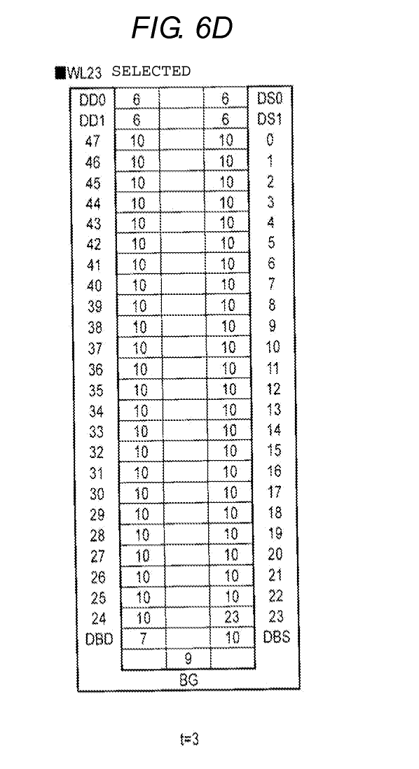

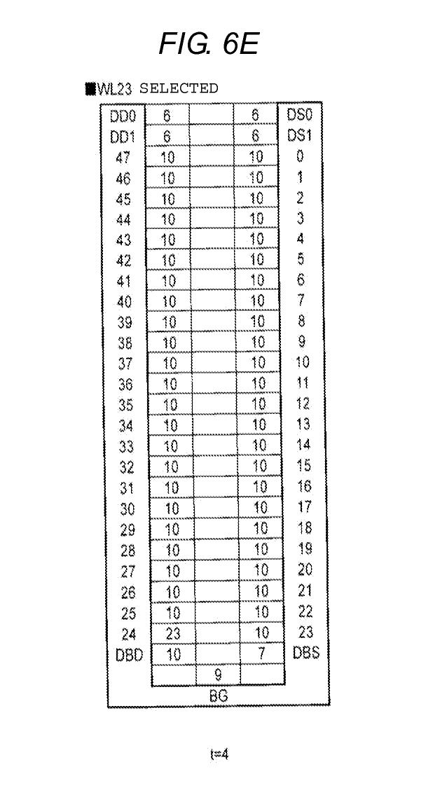

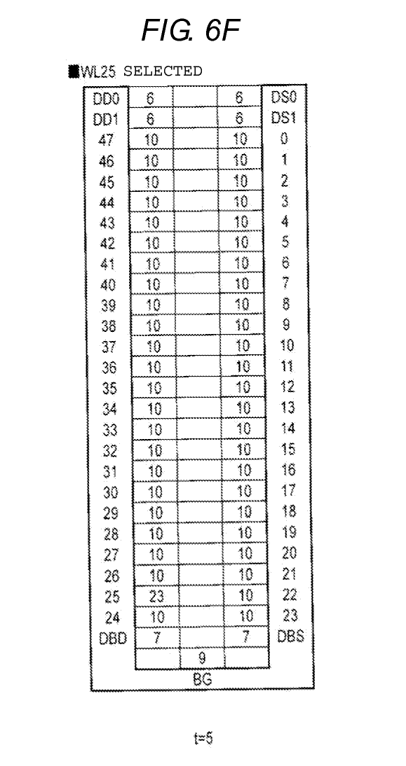

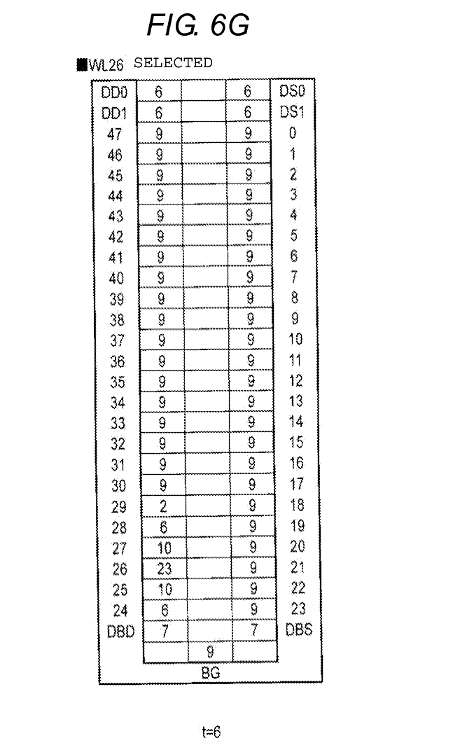

The control circuit 15 generates voltages according to one of plural rules based on this sequence program. In one embodiment, the control circuit 15 selects one of the rules based on a rule selection signal received from the outside controller 2, and the outside controller 2 generates the rule selection signal based on a write address included in a write command received from a host. The plural rules, which include first voltage application rule to fifth voltage application rule, will be described using write operations of FIGS. 4A to 4G and FIGS. 6A to 6G.

Further, the control circuit 15 also participates in the control of input and output states of the input-output circuit 16.

### 1.6 Input-Output Circuit 16

The input-output circuit 16 receives a command, an address, and write data from an external host device (not illustrated), supplies the command and the address to the address-command register 17, and supplies the write data to the data circuit-page buffer 13.

Further, the read data supplied from the data circuit-page buffer 13 is output to the host device under the control of the control circuit 15.

### 1.7 Address-Command Register 17

The address-command register 17 temporarily stores the command and the address supplied from the input-output circuit 16, supplies the command to the control circuit 15, and supplies the address to the row decoder 12 and the column decoder 14.

### 1.8 Internal Voltage Generating Circuit 18

The internal voltage generating circuit 18 generates predetermined voltages under the control of the control circuit 15 during a write operation, a read operation, and an erase operation.

During the write operation, the internal voltage generating circuit 18 generates a voltage VPGM (15.0 V to 23.0 V), a voltage VPASS1 (10V), a voltage VPASS2 (9 V), a voltage VPASS3 (6 V), a voltage VPASS4 (7 V), and a voltage VISO (2 V).

The internal voltage generating circuit 18 supplies the voltage VPGM to the select word line WL, supplies any one of the voltages VPASS1 to VPASS3 and the voltage VISO (2 V) to the non-select word line WL, and supplies the voltage VPASS4 to dummy word lines WLDBD and WLDBS.

The voltage VPGM has a voltage value at which charges are injected into charge accumulation layers (described below) included in the memory cells MC, and thresholds of the memory cell MC are shifted to another level.

The above-described respective voltages such as VPGM and VPASS1 are examples of voltages of a case where a write pulse application operation is performed.

During a write operation, when the non-volatile semiconductor memory device receives write data and starts the write operation, a write cycle including a write pulse application operation and a write verification operation is performed, and the write cycle is repeated until simultaneous write operations of plural memory cells are finished.

Typically, the write voltage VPGM is controlled as follows. In the initial write cycle, the write voltage VPGM is applied to the memory cells at a low voltage at which the memory cells are not over-programmed. Whenever the write cycle is repeated, the write voltage VPGM increases by a predetermined voltage to efficiently write data on all the memory cells.

In addition, the voltage VPASS is optimized as follows. When the voltage VPASS is applied to non-select word lines WL in a selected memory string MS, and when a selected memory cell MC is a target of a write operation during which the threshold is shifted, a write operation is performed on the selected word line WS, a non-write operation during which the threshold does not increase is not performed on the selected memory cell MC, and an erroneous write operation is not performed on the non-select memory cells.

Further, the voltage VISO electrically separates channels, which are continuous in the memory string MS, from the others.

Similarly to the voltage VPASS, the voltage VISO is also optimized regarding the write operation and the non-write operation on the select memory cells and the prevention of the erroneous write operation on the non-select memory cells.

### 3. Write Operation

Next, the write operation will be described with reference to FIGS. 4A to 4G.

FIGS. 4A to 4G are conceptual diagrams illustrating the dummy memory cells MCDD and MCDS, the memory cells MC, the bottom dummy memory cells MCDBD and MCDBS, and voltage values applied to gates of the above-described memory cells during the write operation.

As illustrated in FIGS. 4A to 4G, the write operation is sequentially performed from a source side to a drain side of the memory string MS.

### Write Operation on Memory Cells MC0 to MC20 and Memory Cells MC27 to MC47

As illustrated in FIG. 4A, during a write operation where a word line WL20 is selected, voltages of 2 V, 6 V, and 10 V are supplied to non-select word lines WL which are positioned in a range of the select word line WL±3 on both sides thereof, respectively, and a voltage of 7 V is supplied to the dummy word lines WLDBD and WLDBS.

Specifically, in the example of FIG. 4A, under the control of the control circuit 15, the internal voltage generating circuit 18 applies the write voltage VPGM (23 V) to the select word line WL20, applies the voltage VPASS 1 (10V) to non-select word lines WL19 and WL21 adjacent to the select word line WL20, applies the voltage VPASS2 (6 V) to non-select word lines WL18 and WL22, applies the voltage VISO (2 V) to non-select word lines WL17 and WL23, and applies the voltage VPASS4 (7 V) to the dummy word lines WLDBD and WLDBS.

This rule will be referred to as “the first voltage application rule”.

In addition, a write operation on the memory cells MC0 to MC19 and the memory cells MC27 to MC47 which are not illustrated is performed by the voltages being applied to the respective word lines WL according to the first voltage application rule as illustrated in FIG. 4A.

That is, during the write operation on the memory cells MC0 to MC20 and the memory cells MC27 to MC47, the voltage VPASS4 (7 V) is applied to the dummy word lines WLDBD and WLDBS, the write voltage VPGM (23 V) is applied to the select word line WL, and the voltages of 10V, 6V, and 2V are applied to the non-select word lines WL, which are positioned in a range of the select word line±3, in order from the closest non-select word line to the select word line WL. To dummy word lines WLDD0, WLDD1, WLDS0, and WLDS1, voltages are applied as follows. When the select word line is distant from these dummy word lines by more than ±3, a predetermined voltage (for example, VPASS3) is applied thereto. When the select word line is in a range of the select word line±3, any voltage of 10 V, 6V, and 2 V may be applied thereto according to the distance from the select word line, or a predetermined voltage may be applied thereto irrespective of the position of the select word line.

### Write Operation on Memory Cells MC21 and MC26

FIG. 4B illustrates voltages applied to the respective word lines when the memory cell MC21 is selected, and FIG. 4G illustrates voltages applied to the respective word lines when the memory cell MC26 is selected.

In this case, during the write operation on the memory cells MC21 and MC26, the control circuit 15 adopts not the above-described first voltage application rule but a second voltage application rule described below.

Specifically, under the control of the control circuit 15 adopting the second voltage application rule, the internal voltage generating circuit 18 supplies not the voltage VISO, which is supposed to be supplied to the dummy word lines WLDBD and WLDBS, but the non-selection voltage VPASS4 (7 V) to the dummy word lines WLDBD and WLDBS (refer to FIGS. 4B and 4G).

This is a result of giving priority to the voltage, which is originally applied to the dummy word lines WLDBD and WLDBS, rather than the voltages (here, the voltages of the non-select word lines in a range of the select word line±3) of the non-selection word lines positioned centering on the select word line.

### Write Operation on Memory Cells MC22 to MC25

FIGS. 4C to 4F illustrate a relationship between applied voltages during the write operations where the memory cells MC22 to MC25 are selected.

In this case, the control circuit 15 adopts a third voltage application rule different from the above-described application rules.

Specifically, when each of the word lines WL22 to WL25 is selected for the write operation, the voltage of 10 V is supplied to non-select memory cells adjacent to a write target memory cell MC, and the same voltage (9 V) is supplied to non-select word lines WL positioned around the select word line WL (refer to FIGS. 4C to 4F).

In the example of FIG. 4D, under the control of the control circuit 15 adopting the third voltage application rule, the internal voltage generating circuit 18 applies the write voltage VPGM (23 V) to the select word line WL23, applies the voltage VPASS1 (10 V) to the non-select word line WL22 and the dummy word line WLDBS adjacent to the select word line WL23, and applies the voltage VPASS2 (9 V) to the non-select word lines WL24 and WL25 which are positioned opposite and diagonal to the select word line WL23.

In addition, under the control of the control circuit 15, the internal voltage generating circuit 18 applies the voltage VPASS2 (9 V) to the non-select word lines WL0 to WL16 and WL24 to WL47.

Here, the description is made with reference to FIG. 4D as an example, but the same shall be applied to FIGS. 4E and 4F.

Such control may be achieved by the control circuit 15 identifying that the select word line is in a range of the word lines WL22 to WL25. In this example, although the range of the select word line to which the third voltage application rule is applied is the word lines WL22 to WL25, may be the word lines WL21 to WL26 or may be the word lines WL20 to WL27.

This range is determined in consideration of the application range (the select word line±N; N is a natural number of 1 or more) of the voltages of the non-select word lines positioned centering on the select word line according to the first voltage application rule. That is, the range is determined based on the distance between the select word line and a position to which a low voltage (for example, VISO) affecting on a breakdown voltage between the word lines is applied.

In addition, in this example, when the select word line is any one of the word lines WL22 to WL25, the voltage VPASS2 is applied to the non-select word line WL24 and the like opposite to the select word line. However, instead of the voltage VPASS2, another voltage higher than the voltage VISO may be applied as long as it may alleviate the breakdown voltage between the word lines.

Further, the details of the write operation including the operation of the sense amplifier SA will be described. The sense amplifier SA (not illustrated) transfers a write allowing voltage (0 V) or a non-write voltage (for example, VDD=2.2 V) to the bit lines BL.

For example, when the write allowing voltage is transferred to the bit lines BL, a channel potential generated in the memory string MS0 is 0 V. Therefore, data “0” is written on the memory cell MC23 by a difference between a potential of the select word line WL23 and the channel potential.

In addition, for example, when the non-write voltage is transferred to the bit lines BL, a channel potential generated in the memory string MS0 is in a floating state due to a drain side (bit line side) selector gate which is not illustrated.

The potential for the above-described write operation of the data “0” applied to the bit lines may be transferred to the drain side selector gate while being necessarily in the on-state. In addition, when a bit line potential for a write operation of data “1” is applied, a gate voltage, which is optimized to be in the floating state while being necessarily in the off-state, is applied to the drain side selector gate.

For example, when a threshold voltage of the drain side selector gate is in a range of 1 V to 2 V, a voltage of, for example, 2.5 V is applied to the gate.

In this case, during the write operation of the data “1”, the channel potential of the memory string MS0 is in the floating state after being charged to 0.5 V to 1.5 V.

Next, when each word line voltage illustrated in FIGS. 4A to 4G is applied during the write pulse application operation, the channel potential of the write operation of the data “1” increases while maintaining the floating state due to capacity coupling between each word line and a channel. Therefore, a memory cell to which the write voltage VPGM is applied may be made to be in a non-write state where a write operation is not performed.

Here, an advantageous effect of a case where the first voltage application rule is adopted as illustrated in FIGS. 4A and 4G will be described.

First, when the voltage VPASS or the like is applied to a memory string of the write operation (non-write operation) of data “1”, the channel potential in the floating state is boosted by capacity coupling. However, in a non-select word line to which the voltage VISO is applied, channel boosting does not substantially occur.

Therefore, in a memory cell to which the voltage VISO is applied, a channel potential in a memory string may be separated.

Accordingly, when the voltage VISO is applied to a non-select word line closer to the source side than the select word line, a channel potential on the source side where the write operation is finished may be separated, and a drain side channel region including the select memory cell may be efficiently boosted.

In addition, when the voltage VISO is applied to non-select word lines distant from the select word line to both the source side and the drain side by a predetermined number, local channel boosting occurs by narrowing a channel region including the select memory cell.

As a result, the local channel region may be efficiently boosted. Alternatively, even when the select memory cell is in any region of a memory string, a channel potential to be boosted is uniformly controlled, and a setting margin of the entire memory string for an erroneous write operation may be set to be wide.

However, the voltage VISO should be used with caution.

A voltage range which is applied to plural word lines of a memory string increases, a potential difference between the word lines increases, and thus it is necessary that the breakdown voltage be carefully controlled from two standpoints.

First, regarding the first standpoint, since a difference between applied potentials of upper and lower word lines WL increases, breakdown voltage conditions become strict, an interband tunnel current flows through the inside of a memory string, and an erroneous write operation may occur between a word line WL to which the voltage VPGM is applied and a word line WL to which the voltage VISO is applied.

Therefore, as illustrated in FIG. 4A, one or more non-select word lines are set to be applied with a voltage such as VPASS1 between a select word line to which the write voltage VPGM is applied and a non-select word line to which the voltage VISO is applied.

Regarding the second standpoint, a potential difference between the word lines WL is generated due to the structure of the memory cell array. That is, there is a problem in that the word line WL to which the write voltage is applied and the word line WL to which the voltage VISO is applied face each other with a narrow space interposed therebetween.

In the following description, it is assumed that a write operation is performed by selecting a memory cell MC close to the back gate transistor BG while maintaining the first voltage application rule.

For example, a case where the word line WL22 is selected is assumed.

In this case, the voltage VPGM is applied to the word line WL22, the voltage VPASS1 is applied to the word line WL23, the voltage VPASS2 is applied to the word line WL24, and the voltage VISO is applied to the word line WL25.

Alternatively, a case where the word line WL23 is selected is as follows.

That is, the voltage VPGM is applied to the word line WL23, the voltage VPASS4 is applied to the dummy word line WLDBS, the voltage VPASS4 is applied to the dummy word line WLDBD, and the voltage VISO is applied to the word line WL24.

Due to the voltage application rule, the voltage VISO applied to a non-select word line may be turned back from the back gate transistor and then positioned at a non-select word line position right next to or oblique to the word line to which the write voltage is applied.

In a 3D memory, the cell size is determined in accordance with the size of slits which separate the word lines WL or the size of memory holes.

Regarding the slits of the word lines WL, a word line WL on a lower layer tends to be narrower than a word line WL on an upper layer.

That is, the breakdown voltage between the word lines WL between which slits are interposed tends to decrease toward the word line WL on the lower layer. Accordingly, when the voltages applied to the word lines WL are determined according to the first voltage application rule, short-circuiting may occur between the word lines WL between which slits are interposed.

Alternatively, in order for short-circuiting not to occur, it is necessary that the size of slits be increased, that is, it is necessary that the cell size be set to be large.

Therefore, when the select word line WL is present in a predetermined region close to the back gate transistor BG as in this embodiment, a special voltage application rule of not applying the voltage VISO is applied.

When short-circuiting occurs in the word lines WL, the memory block becomes an unavailable region. Therefore, a voltage application rule in which the voltage VISO is not used in a predetermined region close to the back gate transistor BG is applied.

The voltages which are applied to the respective word lines WL are optimized based on the above-described voltage application rules.

### Effects According to First Embodiment

With the non-volatile semiconductor memory device according to the first embodiment, the effect (1) may be obtained.

### (1) Short-Circuiting Between the Word Lines WL May be Suppressed.

Due to the structure of the memory string MS illustrated in FIG. 2, the distance between two adjacent word lines WL is extremely small.

Therefore, there is a concern that short-circuiting may occur due to a potential difference between a memory cell MC to which the write voltage VPGM (23 V) is supplied and memory cells MC which are positioned opposite and diagonal to the above memory cell and to which, for example, the voltage VISO (2 V) is supplied.

On the other hand, with the non-volatile semiconductor memory device according to the first embodiment, the control circuit 15 supplies predetermined voltages to the respective word lines WL according to the above-described third voltage application rule.

That is, as illustrated in FIGS. 4C to 4F, voltages of, for example 9 V and 10 V are supplied to the memory cells MC which are positioned opposite and diagonal to the select word line WL. Therefore, a potential difference applied between the word lines may be alleviated, and short-circuiting between the memory cells MC may be suppressed.

### Second Embodiment

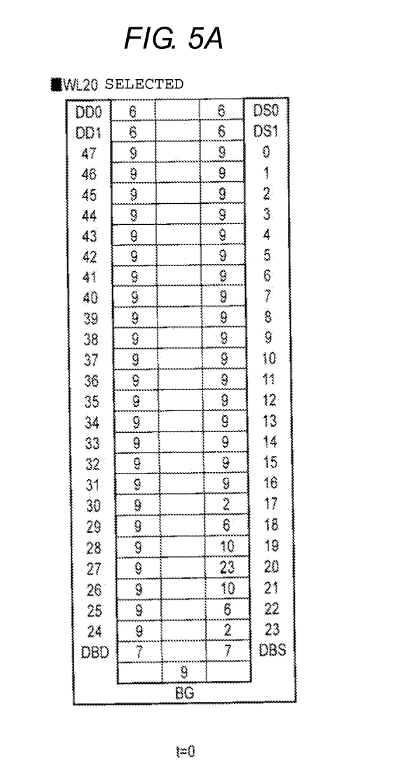

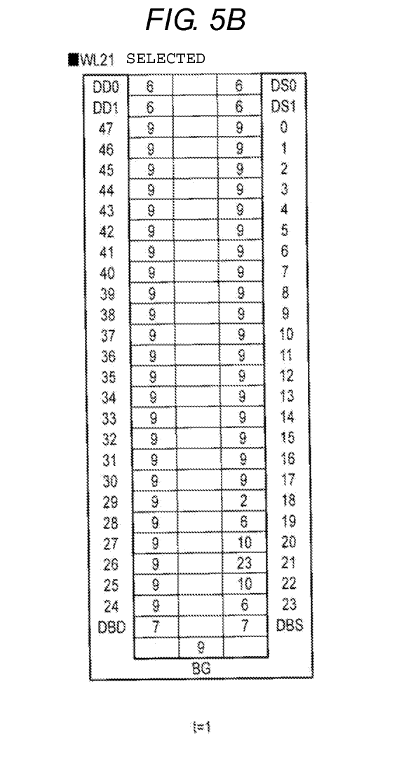

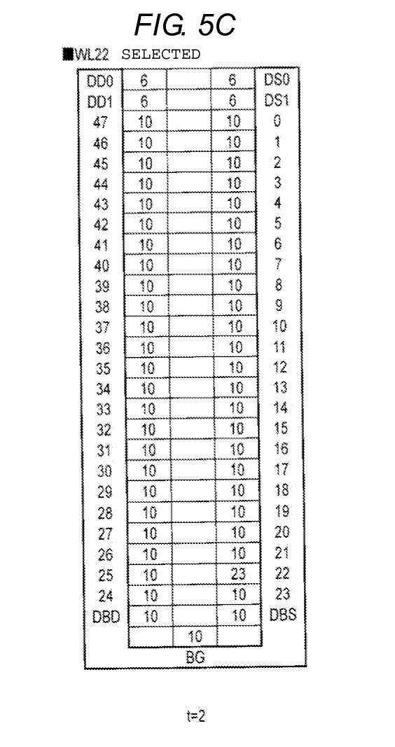

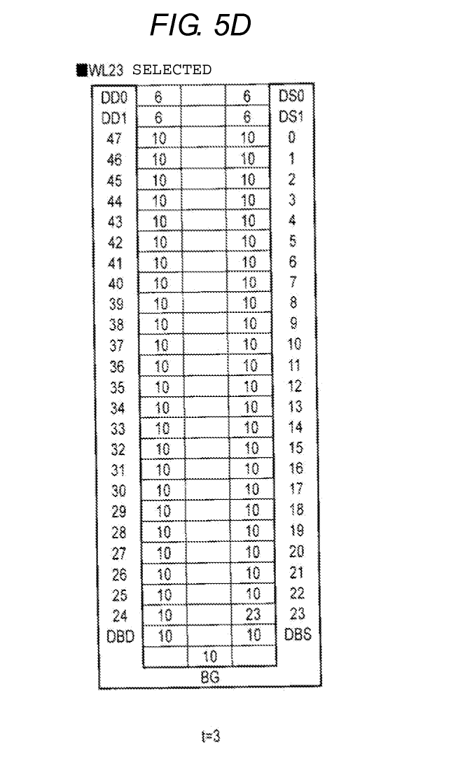

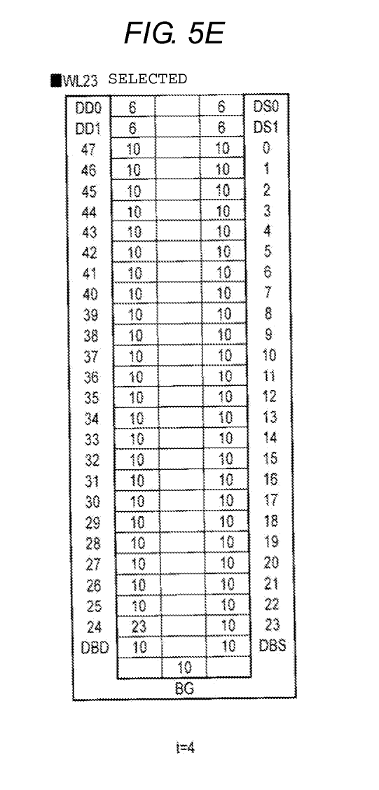

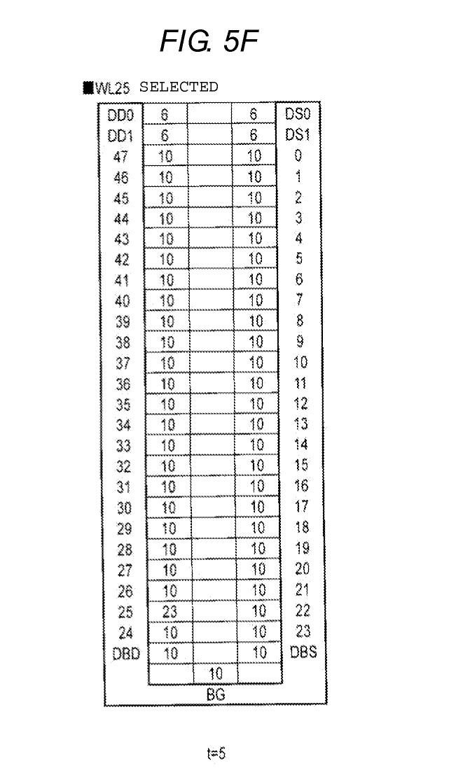

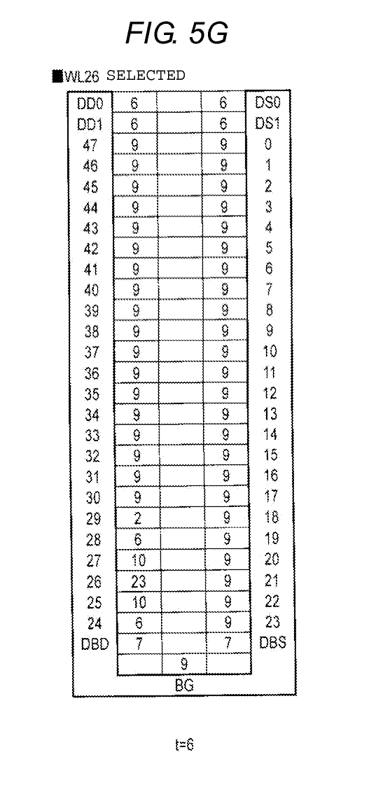

Next, a non-volatile semiconductor memory device according to a second embodiment will be described with reference to FIGS. 5A to 5G. In the second embodiment, the erroneous writing resistance of the first embodiment is further improved. Since the configurations of the second embodiment are the same as those of the first embodiment, the description thereof will not be repeated.

### 1. Write Operation

FIGS. 5A to 5G are conceptual diagrams illustrating the dummy memory cells MCDD and MCDS, the memory cells MC, the bottom dummy memory cells MCDBD and MCDBS, and voltage values applied to gates of the above-described memory cells during the write operation.

Similarly to the above-described case, FIGS. 5A to 5G illustrate the write operations when the memory cells MC20 to MC26 are selected, respectively.

### Write Operation on Memory Cells MC0 to MC20 and Memory Cells MC27 to MC47

As illustrated in FIG. 5A, since the write operation in which the word line WL20 is selected and the write operation on the memory cells MC0 to MC19 and the memory cells MC27 to MC 47 which are not illustrated are the same as those of the first embodiment, the description thereof will not be repeated.

### Write Operation on Memory Cells MC21 and MC26

As illustrated in FIGS. 5B and 5G, since the write operation on the memory cells MC21 and MC26 adopts the second voltage application rule as in the first embodiment, the description thereof will not be repeated.

### Write Operation on Memory Cell MC22, MC23, MC24, and MC25

The write operations of FIGS. 5C, 5D, 5E, and 5F adopt a fourth voltage application rule described below.

Specifically, instead of applying the voltage VPASS2 (9 V) as is done when the third voltage application rule is adopted, the voltage VPASS1 (10 V) is applied to the non-select word lines WL and the dummy word lines WL when the fourth application rule is adopted. The fourth voltage application rule applies to memory cells MC (non-select memory cells MC) positioned on an upper layer of the memory string MS. In the following description, this voltage application rule will be referred to as the fourth voltage application rule.

That is, in the example of FIG. 5D, under the control of the control circuit 15, the internal voltage generating circuit 18 applies the write voltage VPGM (23 V) to the select word line WL23, applies the voltage VPASS 1 (10V) to the non-select word lines WL22 and WL24 adjacent to the select word line WL23, and applies the voltage VPASS1 (10 V) to the non-select word lines WL24 and WL25 which are positioned opposite and diagonal to the select word line WL23, and applies the voltage VPASS1 (10 V) to the dummy word lines WLDBD and WLDBS.

In addition, under the control of the control circuit 15, the internal voltage generating circuit 18 applies the voltage VPASS1 (10 V) to the non-select word lines WL0 to WL21 and WL26 to WL47.

Here, the reason for supplying the voltage VPASS1 (10 V) to the entire memory string MS will be qualitatively described with reference to FIGS. 5A and 5D.

First, FIG. 5A will be described.

In FIG. 5A, the voltage VISO (2 V) is supplied to the non-select word lines WL17 and WL23 positioned at both ends of the select word line WL 20.

Therefore, when this string is not written, channels of the memory cells MC18 to MC22 are electrically closed by the memory cells MC17 and MC23, and the above-described local channel boosting occurs.

However, as illustrated in FIG. 5D, when a voltage which is supplied to the word lines WL (for example, WL20 and WL25) adjacent to the select word line WL is changed from the voltage VISO (2 V) to the voltage VPASS1 (10 V), the above-described electrically closed space is eliminated.

That is, channels of the memory cells MC0 to MC19 and the memory cells MC27 to the MC47 illustrated in FIG. 5D may be electrically connected.

Accordingly, during a non-write operation, a channel of the select memory cell MC23 has a potential which is determined by channel boosting of substantially all the word lines. At this time, when the fourth voltage application rule is applied as it is to the voltages of the respective non-select word lines which are optimized according the voltage application rule of FIG. 5A, the channel potentials may not sufficiently increase. When the channel potentials are not in an appropriate range, an erroneous write operation may be performed.

When a channel potential during the non-write operation of FIG. 4D is lower than that during the non-write operation of FIG. 5A, as illustrated in FIG. 5D, the non-select word line voltages applied to the non-select word lines WL0 to WL20 and WL24 to WL47 and the like are controlled to be high and to obtain sufficient channel potentials where an erroneous write operation does not occur. In this example, the applied voltages including the voltages of the dummy word lines WLDBS and WLDBD and the back gate transistor are higher than those of FIG. 5A.

In word lines, such as the word lines WL24 to WL47, to which a voltage of 10 V is applied, it may be considered that the voltage VPASS2 is changed to the voltage VPASS1. When the voltage VPASS2 is maintained as it is, and when the select word line is in a predetermined range (in this example, the word line WL22 to WL25), it may be considered that the output voltage is changed from 9 V to 10 V.

As a result, an erroneous write operation may be suppressed by increasing the channel potential of the select memory cell MC23 even during a non-write operation.

Conversely, when the increased channel potentials during the non-write operation of FIG. 5A are lower than the increased channel potentials during the non-write operation of FIG. 4D, the non-select word line voltages during the application of the voltage application rule of FIG. 5D may be changed into low voltages.

The channel potentials during a non-write operation are changed by the voltages which are applied to the non-select word lines, the write order to the word lines, and the application word line range of the voltage application rules. Therefore, when the voltage application rule is changed, a potential adjusting method is adjusted and optimized according to circumstances.

Hereinabove, the write operation is described with reference to FIG. 5D as an example. However, since the same shall be applied to FIGS. 5C, 5E, and 5F, the description thereof will not be repeated.

### Effects According to Second Embodiment

With the non-volatile semiconductor memory device according to the second embodiment, the following effect (2) may be obtained in addition to the above-described effect (1).

### (2) An Erroneous Write Operation May be Suppressed (Part 1).

As described above, in the non-volatile semiconductor memory device according to the second embodiment, the voltages which are applied to the non-select word lines WL are changed.

Therefore, the channel potential of the select memory cell MC may be appropriately adjusted while alleviating a potential difference between the word lines described in the first embodiment. Accordingly, an erroneous write operation may be suppressed.

### Third Embodiment

Next, a non-volatile semiconductor memory device according to a third embodiment will be described with reference to FIGS. 6A to 6G. In the third embodiment, the voltages which are supplied to the dummy word lines WLDBD and WLDBS are fixed under given conditions in consideration of the overlapping with the voltage (fixed to 9 V) which is applied to the gate of the back gate transistor BG. As a result, the voltage values applied to the dummy word lines WLDBD and WLDBS are optimized.

Since the configurations of the third embodiment are the same as those of the first and second embodiments, the description thereof will not be repeated. Hereinafter, a write operation according to the third embodiment will be described.

### 1. Write Operation

The write operation will be described with reference to FIGS. 6A to 6G.

FIG. 6A to 6G are schematic diagrams illustrating write operations when the memory cells MC20 to MC26 are selected, respectively, and illustrate the dummy memory cells MCDD and MCDS, the memory cells MC, the bottom dummy memory cells MCDBD and MCDBS, and voltage values applied to gates of the above-described memory cells are illustrated.

### Write Operation on Memory Cells MC0 to MC20 and Memory Cells MC27 to MC47

As illustrated in FIG. 6A, since the write operation in which the word line WL20 is selected and the write operation on the memory cells MC0 to MC19 and the memory cells MC27 to MC 47 which are not illustrated are the same as those of the first and second embodiments, the description thereof will not be repeated.

### Write Operation on Memory Cells MC21 and MC26

As illustrated in FIGS. 6B and 6G, since the write operation on the memory cells MC21 and MC26 adopts the second voltage application rule as in the first and second embodiments, the description thereof will not be repeated.

### Write Operation on Memory Cell MC22, MC23, MC24, and MC25

Next, the write operation on the memory cells MC22, MC23, MC24, and MC25 will be described. The write operations of FIGS. 6C, 6D, 6E, and 6F adopt a fifth voltage application rule described below.

According to the fifth voltage application rule, under the control of the control circuit 15, the internal voltage generating circuit 18 supplies a fixed voltage of 9 V to the gate of the back gate transistor BG. In addition, when the dummy word lines WLDBD and WLDBS are adjacent to the select word line WL, the internal voltage generating circuit 18 changes the voltage supplied to the dummy word lines WLDBD and WLDBS from the voltage VPASS4 (7 V), which is originally applied, to the voltage VPASS1 (10 V).

That is, when the dummy word lines WLDBD and WLDBS are adjacent to the select word line WL, the voltage VPASS1 (10 V) is preferentially supplied to make a relationship between the voltages of the non-select word line adjacent to the select word line be fixed. On the other hand, in other cases, a relationship between the voltage applied to the back gate and the voltages applied to the dummy word lines WLDBD and WLDBS adjacent to the back gate is made to be fixed.

Specifically, in the example of FIG. 6D in which the word line WL23 is selected, under the control of the control circuit 15, the internal voltage generating circuit 18 applies the write voltage VPGM (23 V) to the select word line WL23 and changes the voltage, which is applied to the dummy word line WLDBS adjacent to the select word line WL23, from the voltage VPASS4 (7 V) to the voltage VPASS1 (10 V).

Further, in the example of FIG. 6E, under the control of the control circuit 15, the internal voltage generating circuit 18 applies the write voltage VPGM (23 V) to the select word line WL24 and changes the voltage, which is applied to the dummy word line WLDBD adjacent to the select word line WL23, from the voltage VPASS4 (7 V) to the voltage VPASS1 (10 V).

In this example, since the dummy word line WLDBS is not adjacent to the select word line WL, the internal voltage generating circuit 18 changes the voltage from the voltage VPASS1 (10 V), which is originally applied to the dummy word line WLDBS, to the voltage VPASS4 (7 V).

### Effects According to Third Embodiment

With the non-volatile semiconductor memory device according to the third embodiment, the following effect (3) may be obtained in addition to the above-described effects (1) and (2).

### (3) An Erroneous Write Operation May be Suppressed (Part 2).

In the non-volatile semiconductor memory device according to the third embodiment, as illustrated in FIGS. 6D and 6E, even when the word line WL23 is a write target, the voltage which is applied to the back gate transistor BG and the voltage which is applied to the dummy word lines WLDBD and WLDBS are fixed under give conditions.

The back gate transistor BG has a different shape and different device characteristics from those of other memory cells and dummy memory cells. Accordingly, unless the voltages applied to the dummy word lines adjacent to the back gate transistor BG are set to be optimized, an erroneous write operation is likely to occur during a write operation in which a memory cell close to the back gate transistor is selected. Therefore, if possible, the optimized voltage applied to the back gate transistor BG is maintained to be fixed. However, only with adjacent word line potentials of the select word line, the voltage of the back gate transistor BG is easily affected by the write and non-write characteristics of the select word line and thus is controlled to maintain a predetermined relationship between the applied voltages.

Accordingly, in the non-volatile semiconductor memory device according to the third embodiment, a data erroneous write operation of a case where a word line WL positioned in a lower layer region is a write target may be reduced while alleviating the voltages between the word lines WL positioned in the lower layer region.

During the above-described write operation, under the control of the control circuit 15, the internal voltage generating circuit 18 generates predetermined voltages and applies the voltages to the respective word lines WL, the dummy word lines WLDBS and WLDBD, and the back gate transistor BG, but the present disclosure is not limited thereto.

For example, the internal voltage generating circuit 18 may be controlled by further providing a voltage application rule setting ROM (not illustrated) inside the non-volatile semiconductor memory device 1 of FIG. 1 for the control circuit 15 to refer to this voltage application rule setting ROM.

In this case, the above-described first to fifth voltage application rules are stored in the voltage application rule setting ROM.

In the respective embodiments, the following configurations may be adopted.

### (1) Read Operation

A voltage which is applied to the selected word line during a read operation at level A is, for example, in a range of 0 V to 0.55 V. However, the voltage is not limited to this range and may be in any range of 0.1 V to 0.24 V, 0.21 V to 0.31 V, 0.31 V to 0.4 V, 0.4 V to 0.5 V, and 0.5 V to 0.55 V.

A voltage which is applied to the selected word line during a read operation at level B is, for example, in a range of 1.5 V to 2.3 V. However, the voltage is not limited to this range and may be in any range of 1.65 V to 1.8 V, 1.8 V to 1.95 V, 1.95 V to 2.1 V, and 2.1 V to 2.3 V.

A voltage which is applied to the selected word line during a read operation at level C is, for example, in a range of 3.0 V to 4.0 V. However, the voltage is not limited to this range and may be in any range of 3.0 V to 3.2 V, 3.2 V to 3.4 V, 3.4 V to 3.5 V, 3.5 V to 3.6 V, and 3.6 V to 4.0 V.

The time (tR) of the read operation may be in any range of, for example, 25 μs to 38 μs, 38 μs to 70 μs, and 70 μs to 80 μs.

### (2) Write Operation

The write operation includes a programming operation and a verification operation as described above. During the write operation, the voltage may be in a range described below instead of the above-described range of 15.0 V to 23.0 V.

Specifically, a voltage which is initially applied to the selected word line during the programming operation is in a range of, for example, 13.7 V to 14.3 V. The voltage is not limited to this range and may be in any range of 13.7 V to 14.0 V and 14.0 V to 14.6 V.

A voltage which is initially applied to the selected word line during a write operation of an odd-numbered word line and a voltage which is initially applied to the selected word line during a write operation of an even-numbered word line may be changed.

When the programming operation is performed based on an incremental step pulse program (ISPP), a step-up voltage may be, for example, 0.5 V.

In addition, the voltage which is applied to the non-select word lines may be in a range described below instead of the above-described range of 7.0 V to 10.0 V.

Specifically, the voltage which is applied to the non-select word lines may be in a range of, for example, 6.0 V to 7.3 V. The voltage is not limited to this range and may be in a range of 7.3 V to 8.4 V or may be 6.0 V or lower.

The applied pass voltage may vary depending on whether the non-select word line is an odd-numbered word line or an even-numbered word line.

The time (tProg) of the write operation may be in any range of, for example, 1,700 μs to 1,800 μs, 1,800 μs to 1,900 μs, and 1,900 μs to 2,000 μs.

### (3) Erase Operation

A voltage that is initially applied to a well, which is formed on an upper portion of a semiconductor substrate and above which the above-described memory cells are formed, is in a range of, for example, 12 V to 13.6 V. The voltage is not limited to this range and may be in any range of 13.6 V to 14.8 V, 14.8 V to 19.0 V, 19.0 V to 19.8 v, and 19.8 V to 21 V.

The time (tErase) of the erase operation may be in any range of, for example, 3,000 μs to 4,000 μs, 4,000 μs to 5,000 μs, and 4,000 μs to 9,000 μs.

### (4) Structure of Memory Cell

A charge accumulation layer is provided on a semiconductor substrate (silicon substrate) with a tunnel insulating film having a thickness of 4 nm to 10 nm interposed therebetween. This charge accumulation layer may have a stacked structure which includes an insulating film having a thickness of 2 nm to 3 nm and formed of SiN, SiON, or the like and a polysilicon layer having a thickness of 3 nm to 8 nm. In addition, a metal such as Ru may be added to the polysilicon layer. An insulating film is provided on the charge accumulation layer. This insulating film includes, for example, a lower High-k film having a thickness of 3 nm to 10 nm, an upper High-k film having a thickness of 3 nm to 10 nm, and a silicon oxide film having a thickness of 4 nm to 10 nm that is interposed between the upper and lower High-k films. The High-k films are formed of, for example, HfO. In addition, the thickness of the silicon oxide film may be greater than that of the High-k films. A control electrode having a thickness of 30 nm to 70 nm is formed on the insulating film with a work function adjusting material layer having a thickness of 3 nm to 10 nm interposed therebetween. The work function adjusting material layer is formed of a metal oxide such as TaO or a metal nitride such as Tan. The control electrode may be formed of W or the like.

In addition, air gaps may be formed between the memory cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A non-volatile semiconductor memory device comprising:
a memory cell array that includes a plurality of memory cells stacked above a semiconductor substrate;
a voltage generating circuit configured to generate voltages for a memory cell selected for writing and for non-selected memory cells; and
a control circuit configured to control the voltage generating circuit to supply the voltages to the memory cells,
wherein, if at least a first number of memory cells is between the selected memory cell and the semiconductor substrate, the control circuit applies a first rule, according to which the voltage generating circuit supplies a write voltage to the selected memory cell, a first voltage lower than the write voltage to non-selected memory cells adjacent to the selected memory cell, and a second voltage lower than the first voltage to non-selected memory cells separated from the selected memory cell by one non-selected memory cell, and
wherein, if less than a second number of memory cells is between the selected memory cell and the semiconductor substrate, the control circuit applies a second rule, according to which the voltage generating circuit supplies the write voltage to the selected memory cell and the first voltage to the non-selected memory cells adjacent to the selected memory cell, but does not supply the second voltage to the non-selected memory cells separated from the selected memory cell by one non-selected memory cell.

2. The device according to claim 1, wherein
according to the first rule, the voltage generating circuit supplies a third voltage lower than the second voltage to non-selected memory cells separated from the selected memory cell by two non-selected memory cells, and
according to the second rule, the voltage generating circuit does not supply the third voltage to the non-selected memory cells separated from the selected memory cell by two non-selected memory cells.

3. The device according to claim 2, wherein
according to the second rule, the voltage generating circuit supplies a fourth voltage to all non-selected memory cells excluding dummy memory cells that are separated from the selected memory cell by one or more non-selected memory cells.

4. The device according to claim 1, wherein the non-selected memory cells include dummy memory cells.

5. The device according to claim 4, wherein the first number is three.

6. The device according to claim 5, wherein the second number is also three.

7. The device according to claim 1, wherein the memory cells include first and second strings of serially-connected memory cells connected to each other through a transistor, and according to the second rule, if the selected memory cell is in the first string, the voltage generating circuit supplies a common voltage to all of the memory cells that are in the second string excluding dummy memory cells and, if the selected memory cell is in the second string, the voltage generating circuit supplies a common voltage to all of the memory cells that are in the first string excluding dummy memory cells.

8. The device according to claim 7, wherein, according to the second rule, the voltage generating circuit supplies the common voltage to a gate of the transistor.

9. A non-volatile semiconductor memory device comprising:
a memory cell array that includes a plurality of memory cells stacked above a semiconductor substrate, the memory cells including dummy memory cells;
a voltage generating circuit configured to generate voltages for a memory cell selected for writing and for non-selected memory cells; and
a control circuit configured to control the voltage generating circuit to supply the voltages to the memory cells,
wherein, if at least a first number of memory cells is between the selected memory cell and the semiconductor substrate, the control circuit applies a first rule, according to which the voltage generating circuit supplies a write voltage to the selected memory cell, a first voltage lower than the write voltage to non-selected memory cells adjacent to the selected memory cell, and a second voltage lower than the first voltage to non-selected memory cells separated from the selected memory cell by one non-selected memory cell, and
wherein, if less than a second number of memory cells is between the selected memory cell and the semiconductor substrate, the control circuit applies a second rule, according to which the voltage generating circuit supplies the write voltage to the selected memory cell and the first voltage to all of the non-selected memory cells excluding the dummy memory cells.

10. The device according to claim 9, wherein
according to the first rule, the voltage generating circuit supplies a third voltage lower than the second voltage to non-selected memory cells separated from the selected memory cell by two non-selected memory cells.

11. The device according to claim 10, wherein
according to the first rule, the voltage generating circuit supplies a fourth voltage lower than the first voltage but higher than the second voltage to all non-selected memory cells that are separated from the selected memory cell by three or more non-selected memory cells excluding the dummy memory cells.

12. The device according to claim 9, wherein the memory cells include first and second strings of serially-connected memory cells connected to each other through a transistor, and according to the second rule, if the selected memory cell is in the first string, the voltage generating circuit supplies the first voltage to all of the memory cells that are in the second string excluding the dummy memory cells and, if the selected memory cell is in the second string, the voltage generating circuit supplies the first voltage to all of the memory cells that are in the first string excluding the dummy memory cells.

13. The device according to claim 12, wherein, according to the second rule, the voltage generating circuit supplies the first voltage to a gate of the transistor.

14. The device according to claim 9, wherein the first number is three.

15. The device according to claim 14, wherein the second number is also three.

16. A memory system including a non-volatile semiconductor memory device and a controller configured to generate a rule selection signal based on a write address included in a write command and supply the rule selection signal to the non-volatile semiconductor memory device, wherein the non-volatile semiconductor memory device comprises:
a memory cell array that includes a plurality of memory cells stacked above a semiconductor substrate, each of the memory cells connected to one of a plurality of word lines that are stacked above the semiconductor substrate;
a voltage generating circuit configured to generate voltages for a memory cell selected for writing and for non-selected memory cells; and
a control circuit configured to control the voltage generating circuit to supply the voltages to the memory cells according to the rule selection signal received from the controller.

17. The device according to claim 16, wherein the controller is configured to generate the rule selection signal based on a position of a target word line that is connected to the memory cells of the non-volatile semiconductor memory device that correspond to the write address.

18. The device according to claim 17, wherein
if at least a first number of word lines is between the target word line and the semiconductor substrate, the rule selection signal causes the control circuit to apply a first rule, according to which the voltage generating circuit supplies a write voltage to the selected memory cell, a first voltage lower than the write voltage to non-selected memory cells adjacent to the selected memory cell, and a second voltage lower than the first voltage to non-selected memory cells separated from the selected memory cell by one non-selected memory cell, and
if less than a second number of word lines is between the target word line and the semiconductor substrate, the rule selection signal causes the control circuit to apply a second rule, according to which the voltage generating circuit supplies the write voltage to the selected memory cell and the first voltage to the non-selected memory cells adjacent to the selected memory cell, but does not supply the second voltage to the non-selected memory cells separated from the selected memory cell by one non-selected memory cell.

19. The device according to claim 18, wherein the first number is three.

20. The device according to claim 19, wherein the second number is also three.
